(19) United States
(12) Patent Application Publication
(10) Pub. No.: US 2011/0007572 A1
(43) Pub. Date: Jan. 13, 2011

(54) NAND FLASH MEMORY

(75) Inventors: Koki Ueno, Yokohama-Shi (JP); Satoshi Uchiumi, Yokohama-Shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/723,112

(22) Filed: Mar. 12, 2010

(30) Foreign Application Priority Data
Jul. 9, 2009 (JP) 2009-162515

(51) Int. Cl. G11C 16/06

(52) U.S. Cl. 365/185.22

(57) ABSTRACT

A NAND flash memory has memory cell transistors which data is written into. If number of times the program operation has been executed is not equal to the prescribed upper limit number of times, then the program voltage is set so as to be raised by a first potential difference and then the program operation and the verify operation are executed again, and

only when the number of times of the program operation has become equal to a prescribed number of times being less than the upper limit number of times, the intermediate voltage is raised by a second potential difference and fixed.

### CROSS-REFERENCE TO RELATED APPLICATION

This application is based upon and claims the benefit of priority from the prior Japanese Patent Application No. 2009-162515, filed on Jul. 9, 2009, the entire contents of which are incorporated herein by reference.

### BACKGROUND OF THE INVENTION

1. Field of the Invention

The present invention relates to NAND flash memories in which data is written into memory cell transistors.

2. Background Art

In some conventional NAND flash memories, program operations and verify operations are repeated while raising the program voltage Vpgm applied to the control gate of a selected memory cell transistor stepwise every program loop (see, for example, JP-A 2008-47278 (KOKAI)). As a result, threshold voltages of memory cell transistors having dispersion in write characteristics are written into the same threshold voltages as far as possible.

In the conventional NAND flash memories, writing is stopped on the way for a memory cell in which a desired verify level is exceeded, and writing is conducted again only for a memory cell transistor having a threshold voltage which is equal to or less than the verify level.

In some cases, there is a memory cell transistor in which the threshold voltage rises extremely slowly because of dispersion of the manufacturing process even if the same program voltage Vpgm is applied.

In this case, the memory cell transistor does not pass the verify operation. Therefore, the program loop is executed many times. As a result, the write performance is degraded.

Even if the program loop is executed the upper limit number of times, the memory cell transistor does not pass the verify operation in an extreme case. This results in a problem that the yield falls.

On the other hand, there is also a conventional method of stepping up the program voltage Vpgm every program loop and stepping up an intermediate voltage Vpass applied to control gates of unselected memory cell transistors. As a result, the efficiency of writing into the selected memory cell transistor can be improved.

However, the conventional method has a problem that writing into an unselected memory cell transistor might be falsely conducted (the threshold voltage might rise) if the intermediate voltage becomes high.

### SUMMARY OF THE INVENTION

According to an aspect of the present invention, there is provided: a NAND flash memory in which data is written into memory cell transistors, the NAND flash memory comprising:
a first selection gate transistor connected at a first end to a bit line;
a second selection gate transistor connected at a first end to a source line; and
a plurality of memory cell transistors connected in series between a second end of the first selection gate transistor and a second end of the second selection gate transistor, writing data into each of the memory cell transistors by applying a voltage to a control gate of the memory cell transistor,
wherein
program operation is executed to turn on the first selection gate transistor and to turn off the second selection gate transistor, apply an intermediate voltage to control gates of non-selected first memory cell transistors, and apply a program voltage higher than the intermediate voltage to a control gate of a selected second memory cell transistor,
verify operation is executed after the program operation to verify whether a threshold voltage of the selected second memory cell transistor is equal to or higher than a verify level,
if the threshold voltage of the selected second memory cell transistor is lower than the verify level, then a decision is made after the verify operation whether number of times of the program operation is a prescribed upper limit number of times,
if number of times the program operation has been executed is not equal to the prescribed upper limit number of times, then the program voltage is set so as to be raised by a first potential difference and then the program operation and the verify operation are executed again, and
only when the number of times of the program operation has become equal to a prescribed number of times being less than the upper limit number of times, the intermediate voltage is raised by a second potential difference and fixed.

According to another aspect of the present invention, there is provided: a NAND flash memory in which data is written into memory cell transistors, the NAND flash memory comprising:
a first selection gate transistor connected at a first end to a bit line;
a second selection gate transistor connected at a first end to a source line; and
a plurality of memory cell transistors connected in series between a second end of the first selection gate transistor and a second end of the second selection gate transistor, writing data into each of the memory cell transistors by applying a voltage to a control gate of the memory cell transistor,
wherein
program operation is executed to turn on the first selection gate transistor and turn off the second selection gate transistor, apply an intermediate voltage to control gates of non-selected first memory cell transistors, and apply a program voltage which is higher than the intermediate voltage to a control gate of a selected second memory cell transistor,
verify operation is executed after the program operation to verify whether a threshold voltage of the selected second memory cell transistor is equal to or higher than a verify level,
if the threshold voltage of the selected second memory cell transistor is lower than the verify level, then a decision is made after the verify operation whether number of times of the program operation is a prescribed upper limit number of times,
if number of times the program operation has been executed is not equal to the prescribed upper limit number of times, then the program voltage is set so as to be raised by a first potential difference and then the program operation and the verify operation are executed again, and
only when the program voltage has become equal to a prescribed voltage, the intermediate voltage is raised by a second potential difference and fixed.

### BRIEF DESCRIPTION OF THE DRAWINGS

FIG. 1 is a block diagram showing an example of a NAND flash memory 100 according to a first embodiment, which is a mode of the present invention;

FIG. 2 is a circuit diagram showing a configuration of a memory cell array shown in FIG. 1;

FIG. 3 is a sectional view showing a section of one memory cell transistor M in the memory cell 1 shown in FIG. 2;

FIG. 4 is a sectional view showing a section of the selection gate transistor S1 or S2 in the memory cell array 1 shown in FIG. 2;

FIG. 5 is a sectional view showing a section of memory cell transistors M connected in series in a NAND cell unit 1a1 in the NAND flash memory 100 shown in FIG. 2;

FIG. 6 is a diagram showing an example of potentials at various parts of the NAND cell unit 1a1 shown in FIG. 5 at the time of program operation;

FIG. 7 is a diagram showing an example (a case of eight values) of distribution of threshold voltages of memory cell transistors M in the NAND flash memory 100;

FIG. 8 is a flow chart showing an example of a program loop of the NAND flash memory 100 according to the first embodiment;

FIG. 9 is a waveform diagram showing an example of waveforms of the program voltage Vpgm and the intermediate voltage Vpass in the case where the number n of times of looping of the program loop is in the neighborhood of an upper limit number of times of looping;

FIG. 10 is a waveform diagram showing another example of waveforms of the program voltage Vpgm and the intermediate voltage Vpass in the case where the number n of times of looping of the program loop is in the neighborhood of an upper limit number of times of looping;

FIG. 11 is a sectional view schematically showing an example of relations among capacitances in the vicinity of the selected memory cell transistor M;

FIG. 12 is a flow chart showing an example of a program loop of the NAND flash memory 100 according to the second embodiment;

FIG. 13 is a waveform diagram showing an example of waveforms of the program voltage Vpgm and the intermediate voltage Vpass in the case where the program voltage Vpgm is set in the neighborhood of a program upper limit voltage Vpgmmax; and

FIG. 14 is a waveform diagram showing another example of waveforms of the program voltage Vpgm and the intermediate voltage Vpass in the case where the program voltage Vpgm is set in the neighborhood of the program upper limit voltage Vpgmmax.

### DETAILED DESCRIPTION

Embodiments of the present invention will now be described with reference to the drawings.

### First Embodiment

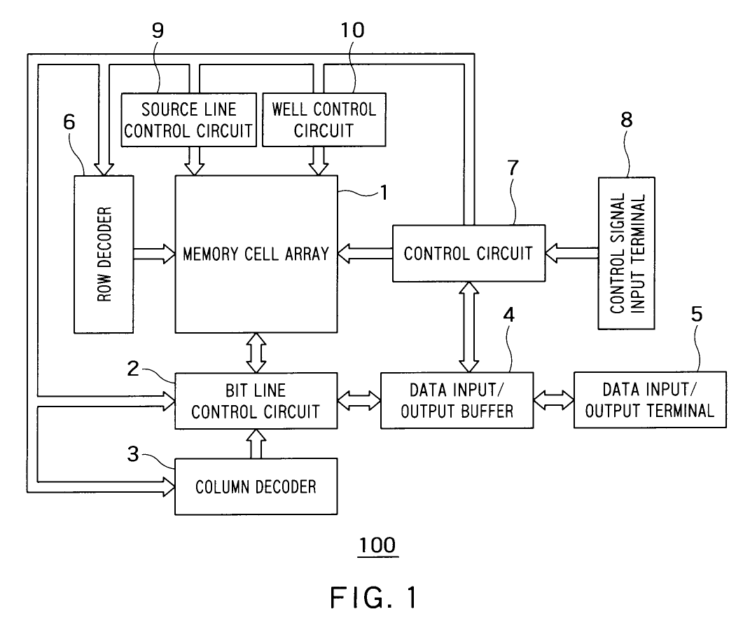

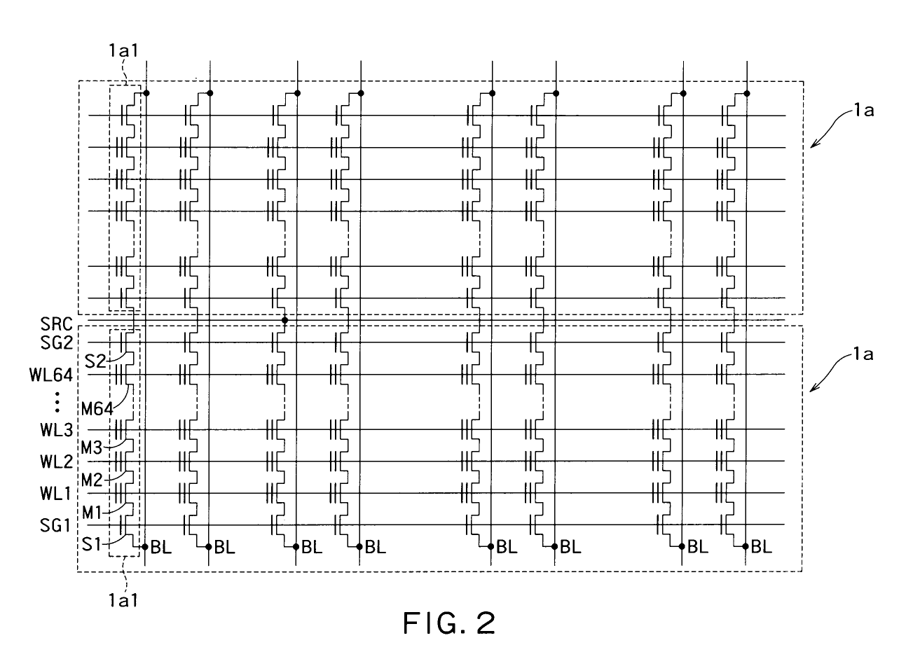

FIG. 1 is a block diagram showing an example of a NAND flash memory 100 according to a first embodiment, which is a mode of the present invention. FIG. 2 is a circuit diagram showing a configuration of a memory cell array shown in FIG. 1.

As shown in FIG. 1, the NAND flash memory 100 includes a memory cell array 1, a bit line control circuit 2, a column decoder 3, a data input/output buffer 4, a data input/output terminal 5, a row decoder 6, a control circuit 7, a control signal input terminal 8, a source line control circuit 9, and a well control circuit 10.

The memory cell array 1 includes a plurality of bit lines BL, a plurality of word lines WL, and a common source line SRC. In the memory cell array 1, for example, memory cell transistors M in which data can be electrically rewritten are arranged in a matrix form.

The bit line control circuit 2 for controlling voltages on the bit lines BL and the row decoder for controlling voltages on the word lines WL are connected to the memory cell array 1. The memory cell transistors M are arranged so as to be divided into a plurality of blocks. At the time of data erasing operation, one of the blocks is selected by the row decoder 6 and remaining blocks are unselected.

The bit line control circuit 2 includes data storage circuits (not illustrated) each playing roles of both a sense amplifier (not illustrated) which senses and amplifies the voltage on the bit line BL in the memory cell array 1 and a data latch circuit for latching data to be written.

The bit line control circuit 2 reads out data in a memory cell transistor M included in the memory cell array 1 via a bit line BL, detects a state of the memory cell transistor M via the bit line BL, and conducts writing (programming) into the memory cell transistor M by applying a write control voltage to the memory cell transistor M via the bit line BL.

The column decoder 3 and the data input/output buffer 4 are connected to the bit line control circuit 2. A data storage circuit in the bit line control circuit 2 is selected by the column decoder 3, and data in the memory cell transistor M read out into the data storage circuit is output to the outside from the data input/output terminal 5 via the data input/output buffer 4.

Write data which is input from the outside to the data input/output terminal 5 is stored in the data storage circuit selected by the column decoder 3, via the data input/output buffer 4.

The row decoder 6 is connected to the memory cell array 1. The row decoder 6 applies a voltage required to read, write or erase data, to the word line WL and select lines SG1 and SG2 in the memory cell array 1.

The source line control circuit 9 is connected to the memory cell array 1. The source line control circuit 9 is adapted to control a voltage on the source line SRC.

The well control circuit 10 is connected to the memory cell array 1. The well control circuit 10 is adapted to control a voltage on a semiconductor substrate (well) on which the memory cell transistors M are formed.

The control circuit is adapted to control the memory cell array 1, the bit line control circuit 2, the column decoder 3, the data input/output buffer 4, the row decoder 6, the source line control circuit 9, and the well control circuit 10.

It is now supposed that a boost circuit (not illustrated) which boosts a power supply voltage is included in the control circuit 7. The control circuit 7 is adapted to boost the power supply voltage by using the boost circuit as occasion demands, and supply the boosted voltage to the bit line control circuit 2, the column decoder 3, the data input/output buffer 4, the row decoder 6, the source line control circuit 9, and the well control circuit 10.

The control circuit 7 conducts control operation in response to a control signal which is input from the outside via the control signal input terminal 8. In other words, the control circuit 7 generates a predetermined voltage in response to the control signal at the time of data writing (programming), verifying, reading and erasing to supply the predetermined voltage to each part in the memory cell array 1, and controls the data writing (programming), verifying, reading and erasing.

As shown in FIG. 2, the memory cell array 1 includes a block 1a formed by connecting a plurality of NAND cell units 1a1 as already described.

One NAND cell unit 1a1 is formed of, for example, sixty-four memory cell transistors M1, M2, . . . , M64 connected in series, a selection gate transistor S1 connected to the memory cell transistor M1, and a selection gate transistor S2 connected to the memory cell transistor M64.

In some cases, the memory cell transistor M1, M2, . . . , M64 is referred to simply as memory cell transistor M as well as already described for simplicity.

The first selection gate transistor S1 is connected to the bit line BL. The second selection gate transistor S2 is connected to the source line SRC.

Control gates of the memory cell transistors M1, M2, . . . , M64 arranged in rows are connected to word lines WL1, WL2, . . . , WL64, respectively.

In some cases, the word line WL1, WL2, . . . , WL64 is referred to simply as word line WL as well as already described for simplicity.

Gates of the first selection gate transistors S1 are connected in common to the select line SG1. Gates of the second selection gate transistors S2 are connected in common to the select line SG2.

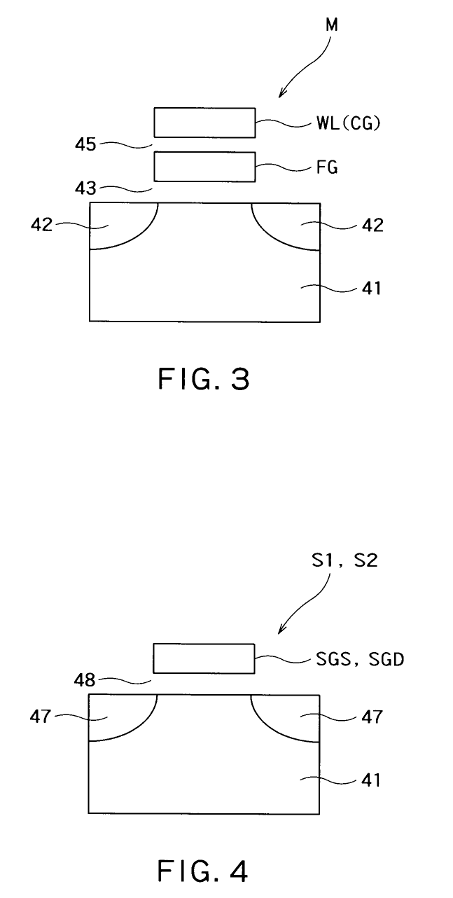

FIG. 3 is a sectional view showing a section of one memory cell transistor M in the memory cell 1 shown in FIG. 2. By the way, in the ensuing description, the memory cell transistor M corresponds to one of the memory cell transistors M1 to M64 shown in FIG. 2.

As shown in FIG. 3, the memory cell transistor M includes a floating gate FG, a control gate (the word line WL), and a diffusion layer 42.

The diffusion layer 42 which becomes a source-drain region of the memory cell transistor M is formed in a well (hereafter referred to simply as semiconductor substrate as well) 41 formed in a semiconductor substrate. Furthermore, the floating gate FG is formed over the well 41 via a gate insulation film (tunnel insulation film) 43. The control gate CG (word line WL) is formed over the floating gate FG via a gate insulation film 45.

The memory cell transistor M is adapted to store data according to threshold voltage. The threshold voltage depends upon a charge quantity stored in the floating gate FG. The charge quantity in the floating gate FG can be changed by a tunnel current which flows through the gate insulation film 43.

In other words, if the control gate CG (word line WL) is supplied with a voltage which is sufficiently higher than that of the well 41 and the diffusion layer (source-drain region) 42, then electrons are injected into the floating gate FG through the gate insulation film 43. As a result, the threshold voltage of the memory cell transistor M becomes higher.

On the other hand, if the well 41 and the diffusion layer (source-drain region) 42 is supplied with a voltage which is sufficiently higher than that of the control gate CG (word line WL), then electrons are discharged from the floating gate FG through the gate insulation film 43. As a result, the threshold voltage of the memory cell transistor M becomes lower.

In this way, data stored in the memory cell transistor M can be rewritten by controlling the quantity of charge stored in the floating gate FG.

FIG. 4 is a sectional view showing a section of the selection gate transistor S1 or S2 in the memory cell array 1 shown in FIG. 2.

As shown in FIG. 4, a diffusion layer 4 which becomes the source-drain region of the selection gate transistor S1 or S2 is formed in the well 41. A control gate SGS or SGD is formed over the well 41 via a gate insulation film 48. The control gates SGS and SGD are connected to the select lines SG1 and SG2 shown in FIG. 2.

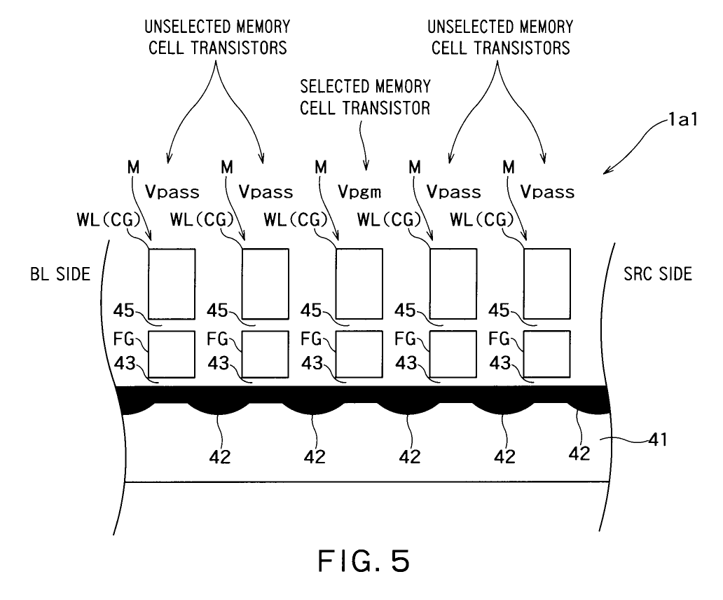

FIG. 5 is a sectional view showing a section of memory cell transistors M connected in series in a NAND cell unit 1a1 in the NAND flash memory 100 shown in FIG. 2. In FIG. 5, the same characters as those in FIG. 3 denote elements like those in FIG. 3.

In FIG. 5, the left side is the bit line BL side and the right side is the source line SRC side. As already described, the NAND cell unit 1a1 includes a memory cell column formed of a plurality of memory cell transistors M connected in series and selection gate transistors (not illustrated) respectively connected to both sides of the memory cell column.

Furthermore, the bit line BL is connected to the memory cell column via the selection gate transistor located on the bit line side as already described. The source line SRC is connected to the memory cell column via the selection gate transistor located on the source line side.

FIG. 5 shows a state of the NAND flash memory 100 at the time of program operation. In other words, a program voltage Vpgm is applied to the control gate CG (word line WL) of a selected memory cell transistor M (here, for example, one memory cell transistor M), and an intermediate voltage Vpass is applied to the control gates CG (word lines WL) of unselected memory cell transistors M.

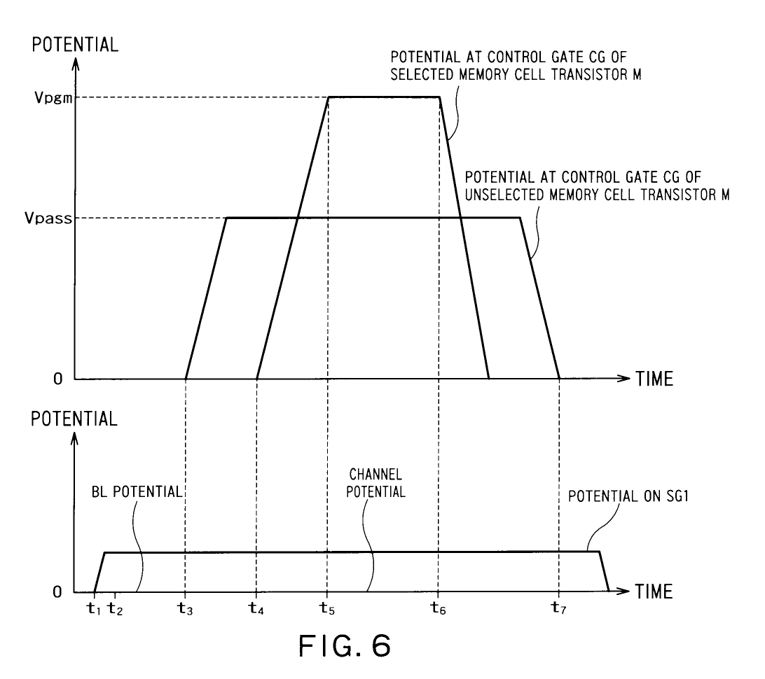

FIG. 6 is a diagram showing an example of potentials at various parts of the NAND cell unit 1a1 shown in FIG. 5 at the time of program operation.

In FIG. 6, the control gate SGS of the selection gate transistor S2 on the source line side are fixed to 0 V. In other words, the selection gate transistor S2 on the source line side is set so as to be in the off-state.

As shown in FIG. 6, the selection gate transistor S1 on the bit line BL side is turned on by raising the potential on the select line SG1 at time t1.

In this state, the intermediate voltage Vpass which is higher than a readout voltage of the memory cell transistor M and which is lower than the program voltage Vpgm is applied to the control gates CG (word lines WL) of unselected memory cell transistors M (time t3 to t7).

Thereafter, the potential at the control gate CG of the selected memory cell transistor M is raised (time t4 and thereafter). The program voltage Vpgm for writing which is higher than the intermediate voltage Vpass is applied to the control gate CG of the selected memory cell transistor M (time t5 to t6).

As a result, the electric field between the floating gate FG and the channel in the selected memory cell transistor M becomes strong, and negative charges are injected. In other words, the threshold voltage of the selected memory cell transistor M is raised to a higher threshold voltage.

Since the intermediate voltage Vpass is lower than the program voltage Vpgm, the threshold voltage of the unselected memory cell transistors M does not basically change. In the present invention, the intermediate voltage Vpass is raised at certain timing in the repeated program loop. As a result, the write efficiency is improved for the selected memory cell transistor M which does not pass the verify operation.

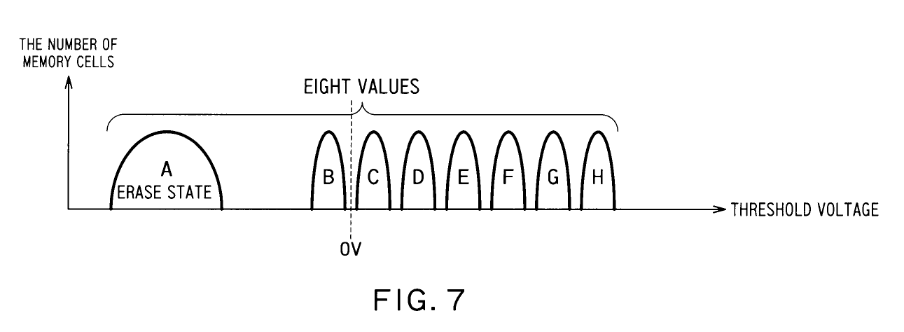

FIG. 7 is a diagram showing an example (a case of eight values) of distribution of threshold voltages of memory cell transistors M in the NAND flash memory 100. In the case shown in FIG. 7, eight data “A,” “B,” “C,” “D,” “E,” “F,” “G” and “H” are assigned in order beginning with the erase state.

An example of a program loop of the NAND flash memory 100 having the configuration heretofore described will now be described.

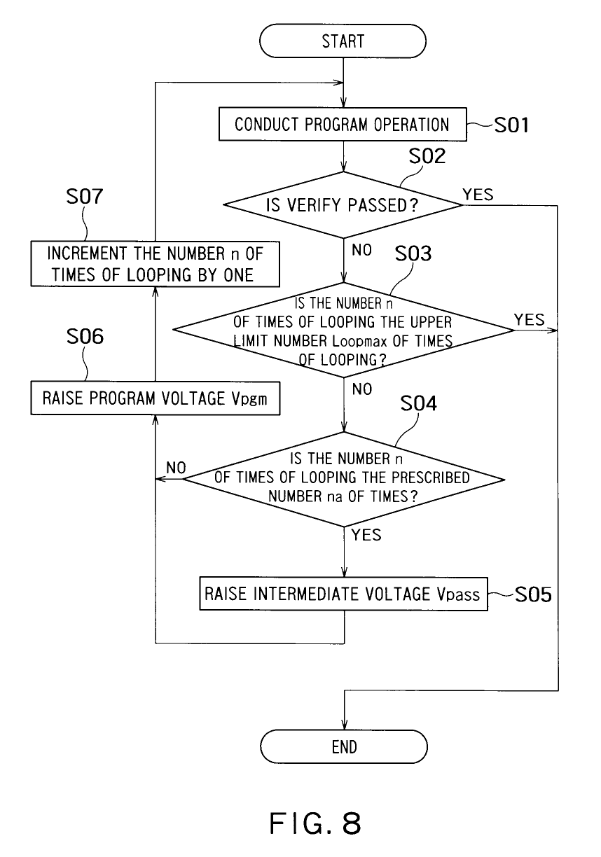

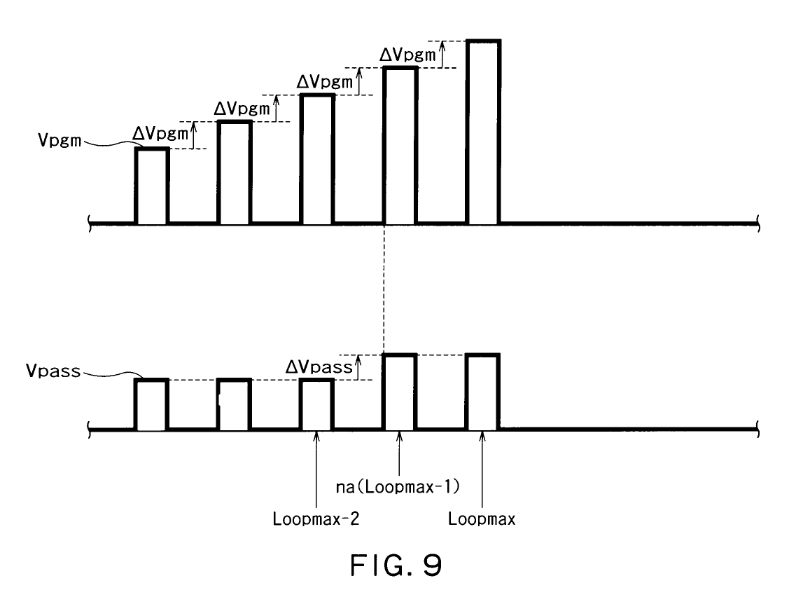

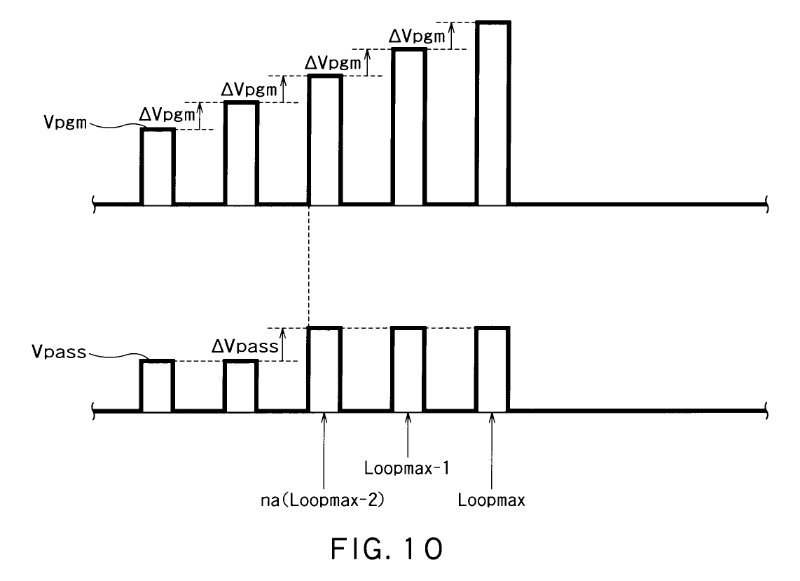

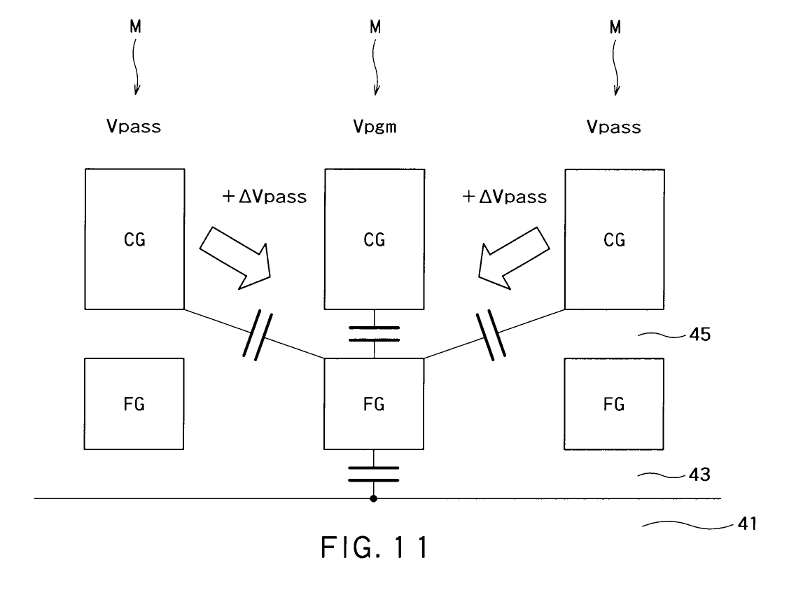

FIG. 8 is a flow chart showing an example of a program loop of the NAND flash memory 100 according to the first embodiment. FIG. 9 is a waveform diagram showing an example of waveforms of the program voltage Vpgm and the intermediate voltage Vpass in the case where the number n of times of looping of the program loop is in the neighborhood of an upper limit number of times of looping. FIG. 10 is a waveform diagram showing another example of waveforms of the program voltage Vpgm and the intermediate voltage Vpass in the case where the number n of times of looping of the program loop is in the neighborhood of an upper limit number of times of looping. FIG. 11 is a sectional view schematically showing an example of relations among capacitances in the vicinity of the selected memory cell transistor M.

The program loop means repetition of the program operation and the verify operation as already described. In the initial state of the program loop, the number n of times of looping of the program loop is set equal to the initial number of times “1.” The program voltage Vpgm and the intermediate voltage Vpass are also set equal to prescribed values.

As shown in FIG. 8, the control circuit 7 conducts program operation on the selected memory cell transistor M in order to store data in the selected memory cell transistor M (step S01). In other words, for example, the control circuit 7 exercises control so as to turn on the first gate transistor S1 and to turn off the second selection gate transistor S2, apply the predetermined intermediate voltage Vpass to the control gates CG of the unselected memory cell transistors M, and apply the program voltage Vpgm which is higher than the intermediate voltage Vpass to the control gate CG of the selected memory cell transistor M (which is now supposed to be one in number) as shown in FIG. 6 and already described. As a result, the threshold voltage of the selected memory cell transistor M is raised.

Then, the control circuit 7 executes the verify operation to verify whether the threshold voltage of the selected memory cell transistor M is equal to at least a predetermined verify level (step S02). If the threshold voltage of the selected memory cell transistor M is equal to at least the verify level, then the control circuit 7 regards the verify operation as passed (regards the program as completed) and finishes the program loop.

On the other hand, if the threshold voltage of the selected memory cell transistor M is less than the verify level, then the control circuit 7 makes a decision whether the number n of times of looping of the program loop (i.e., the number of times the program operation has been executed) is equal to a prescribed upper limit number Loopmax of times of looping (step S03). By the way, the upper limit number Loopmax of times of looping is set according to, for example, specifications of the NAND flash memory 100.

If the number n of times of looping of the program loop is judged to be equal to the upper limit number Loopmax of times of looping at the step S03, then the control circuit 7 regards programming (writing) into the selected memory cell transistor M as impossible and finishes the program loop.

On the other hand, if the number n of times of looping of the program loop is judged to be unequal to the upper limit number Loopmax of times of looping at the step S03, then the control circuit 7 makes a decision whether the number n of times of looping is equal to a prescribed number na of times (step S04).

If the number n of times of looping of the program loop is judged to be equal to the prescribed number na of times at the step S04, then the control circuit 7 sets the intermediate voltage Vpass to a voltage raised by a potential difference ΔVpass (step S05). After the step S05, the control circuit 7 proceeds to a subsequent step S06.

After the intermediate voltage Vpass is raised by the potential difference ΔVpass, the intermediate voltage Vpass is kept constant.

The prescribed number na of times is set equal to a number of times which is less than the upper limit number Loopmax of times of looping. The prescribed number na of times is set equal to a number of times which is in the neighborhood of the upper limit number Loopmax of times of looping, for example, the upper limit number Loopmax of times of looping minus one, or the upper limit number Loopmax of times of looping minus two.

On the other hand, if the number n of times of looping of the program loop is judged to be unequal to the number na of times of looping of the program loop at the step S04, then the control circuit 7 proceeds to the step S6 already described.

At the step S06, the control circuit 7 sets the program voltage Vpgm equal to a voltage raised by the potential difference ΔVpgm. By the way, if the program voltage Vpgm arrives at a program upper limit voltage Vpgmmax, the program voltage Vpgm is fixed to the program upper limit voltage Vpgmmax. The program upper limit voltage Vpgmmax is set considering the capability of the boost circuit already described and the leak current of the NAND flash memory 100.

Here, capacitance between the floating gate FG of the selected memory cell transistor M and the control gate CG of an adjacent unselected memory cell transistor M is smaller than capacitance between the control gate CG and the floating gate FG in the selected memory cell transistor M. Preferably, therefore, the potential difference ΔVpgm is set equal to the potential difference ΔVpass or less. As a result, it is possible to improve the boost efficiency at the floating gate FG of the selected memory cell transistor M.

Then, the control circuit 7 increments the number n of times of looping by one (increments the count by one) (step S07). After the step S07, the control circuit 7 returns to the step S01. Thereafter, a flow similar to the above-described flow is executed.

If the number of times the program operation has been executed is not equal to the upper limit number Loopmax of times of looping in the flow described heretofore, then the program voltage Vpgm is set so as to be raised by the potential difference ΔVpgm, and then the program operation and the verify operation are executed again. And only in the case where the number of times the program operation has been executed has become less than the upper limit number Loopmax of times of looping and has become the prescribed number na of times, the intermediate voltage Vpass is raised by the potential difference ΔVpass and fixed.

If, for example, the prescribed number na of times is equal to the upper limit number Loopmax of times of looping minus one, then the program voltage Vpgm is raised by the potential difference ΔVpgm every program loop as shown in FIG. 9. On the other hand, the intermediate voltage Vpass is raised by the potential difference ΔVpass only when the number n of times of looping is equal to the prescribed number na of times (Loopmax−1).

For example, if the prescribed number na of times is equal to the upper limit number Loopmax of times of looping minus two, then the program voltage Vpgm is raised by the potential difference ΔVpgm every program loop as shown in FIG. 10. On the other hand, the intermediate voltage Vpass is raised by the potential difference ΔVpass only when the number n of times of looping is equal to the prescribed number na of times (Loopmax−2).

In this way, the prescribed number of times na is set so as to correspond to immediately before the number n of times of looping becomes the upper limit number Loopmax of times of looping, such as the upper limit number Loopmax of times of looping minus one or the upper limit number Loopmax of times of looping minus two. As a result, the intermediate voltage Vpass rises by the potential ΔVpass immediately before the program loop finishes. In other words, the boost efficiency is improved and the programming is facilitated for a memory cell transistor M which is difficult to be programmed, immediately before the program loop is finished (FIG. 11).

In the present embodiment, therefore, the probability that a memory cell transistor M which is difficult to be programmed will be completed in programming can be made high as compared with the case where the intermediate voltage Vpass is fixed to a constant value.

Furthermore, in the present embodiment, the intermediate voltage Vpass is kept constant until immediately before the number n of times of looping arrives at the upper limit number Loopmax of times of looping. As a result, programming is completed early for a memory cell transistor M which can be programmed easily. In this case, therefore, the intermediate voltage Vpass is not raised. As a result, false writing into unselected memory cell transistors M can be suppressed.

In other words, in the present embodiment, false writing into unselected memory cell transistors M can be suppressed as compared with the already described conventional art in which the intermediate voltage Vpass is raised stepwise with the object of improving only the boost efficiency.

In the present embodiment, the case where the intermediate voltage Vpass applied to the control gates CG of all unselected memory cell transistors M is increased by the potential difference ΔVpass has been described.

Alternatively, only the intermediate voltage Vpass applied to the control gate(s) CG of one of or both unselected memory cell transistors M adjacent to the selected memory cell transistor M may be increased by the potential difference ΔVpass, while fixing the intermediate voltage Vpass applied to the control gates CG of remaining unselected memory cell transistors M to an initially set voltage.

In this case, false writing into unselected memory cell transistors M apart from the selected memory cell transistor M can be suppressed.

In the NAND flash memory according to the present embodiment, it is possible to improve the writing efficiency while suppressing false writing as heretofore described.

### Second Embodiment

In the first embodiment, the case where the intermediate voltage Vpass is raised when the number n of times of looping of the program loop is the prescribed number na of times has been described.

In the present second embodiment, the case where the intermediate voltage Vpass is raised when the program voltage Vpgm is equal to a prescribed voltage Va will be described. By the way, the present second embodiment is applied to the NAND flash memory 100 according to the first embodiment shown in FIGS. 1 to 7 in the same way.

An example of a program loop of the NAND flash memory 100 according to the second embodiment will now be described.

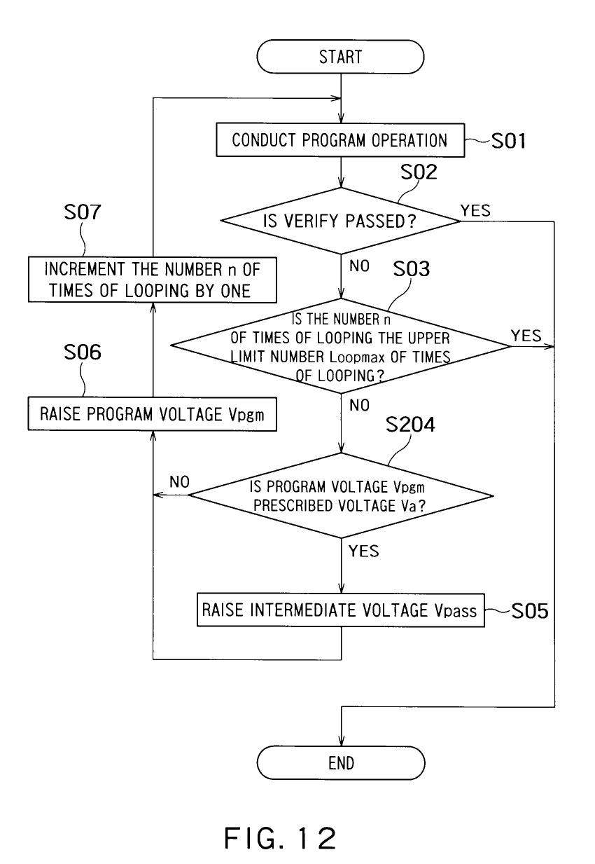

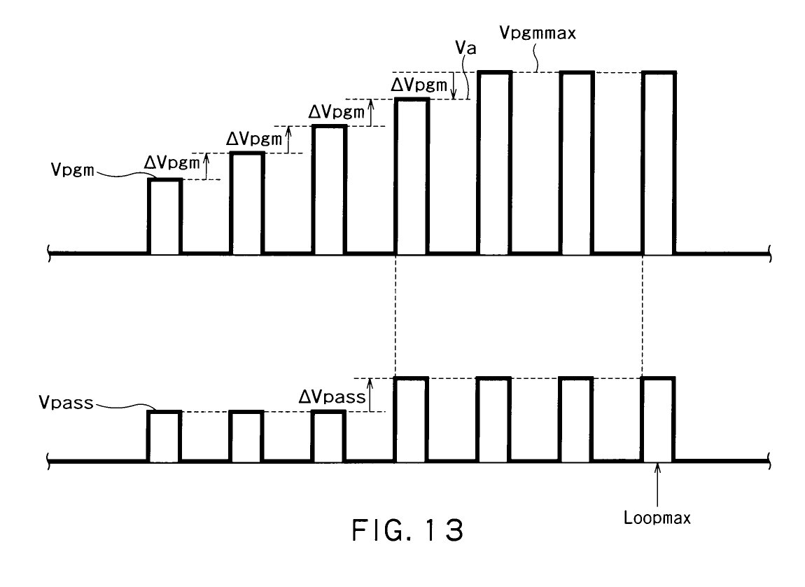

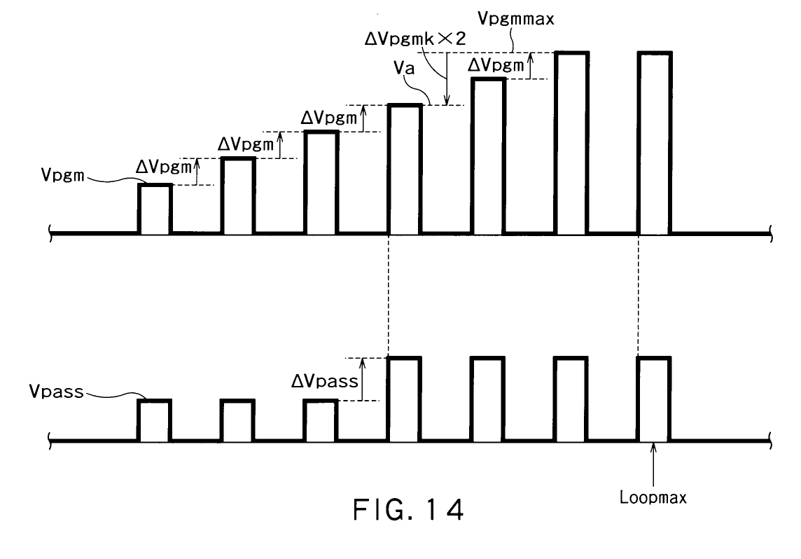

FIG. 12 is a flow chart showing an example of a program loop of the NAND flash memory 100 according to the second embodiment. FIG. 13 is a waveform diagram showing an example of waveforms of the program voltage Vpgm and the intermediate voltage Vpass in the case where the program voltage Vpgm is set in the neighborhood of a program upper limit voltage Vpgmmax. FIG. 14 is a waveform diagram showing another example of waveforms of the program voltage Vpgm and the intermediate voltage Vpass in the case where the program voltage Vpgm is set in the neighborhood of the program upper limit voltage Vpgmmax.

The program loop means repetition of the program operation and the verify operation as already described. In the initial state of the program loop, the number n of times of looping of the program loop is set equal to the initial number of times “1.” The program voltage Vpgm and the intermediate voltage Vpass are also set equal to prescribed values.

As shown in FIG. 12, the control circuit 7 conducts program operation on the selected memory cell transistor M in order to store data in the selected memory cell transistor M (step S01). In other words, for example, the control circuit 7 exercises control so as to turn on the first selection gate transistor S1 and to turn off the second selection gate transistor S2, apply the predetermined intermediate voltage Vpass to the control gates CG of the unselected memory cell transistors M, and apply the program voltage Vpgm which is higher than the intermediate voltage Vpass to the control gate CG of the selected memory cell transistor M as shown in FIG. 6 and already described. As a result, the threshold voltage of the selected memory cell transistor M is raised.

Then, the control circuit 7 executes the verify operation to verify whether the threshold voltage of the selected memory cell transistor M is equal to at least a predetermined verify level (step S02). If the threshold voltage of the selected memory cell transistor M is equal to at least the verify level, then the control circuit 7 regards the verify operation as passed (regards the program as completed) and finishes the program loop.

On the other hand, if the threshold voltage of the selected memory cell transistor M is less than the verify level, then the control circuit 7 makes a decision whether the number n of times of looping of the program loop (i.e., the number of times the program operation has been executed) is equal to a prescribed upper limit number Loopmax of times of looping (step S03). By the way, the upper limit number Loopmax of times of looping is set according to, for example, specifications of the NAND flash memory 100.

If the number n of times of looping of the program loop is judged to be equal to the upper limit number Loopmax of times of looping at the step S03, then the control circuit 7 regards programming (writing) into the selected memory cell transistor M as impossible and finishes the program loop.

On the other hand, if the number n of times of looping of the program loop is judged to be unequal to the upper limit number Loopmax of times of looping at the step S03, then the control circuit 7 makes a decision whether the program voltage Vpgm is equal to the prescribed voltage Va (step S204).

If the program voltage Vpgm is judged to be equal to the prescribed voltage Va at the step S204, then the control circuit 7 sets the intermediate voltage Vpass to a voltage raised by a potential difference ΔVpass (step S05). After the step S05, the control circuit 7 proceeds to a subsequent step S06.

After the intermediate voltage Vpass is raised by the potential difference ΔVpass, the intermediate voltage Vpass is kept constant.

The prescribed voltage Va is set equal to a voltage equal to or less than the program upper limit voltage Vpgmmax, which is a prescribed upper limit of the program voltage Vpgm. The prescribed voltage Va is set to a voltage in the neighborhood of the program upper limit voltage Vpgmmax, for example, a voltage obtained by subtracting the potential difference ΔVpgm from the program upper limit voltage Vpgmmax (the program upper limit voltage Vpgmmax−the potential difference ΔVpgm) or a voltage obtained by subtracting twice the potential difference ΔVpgm from the program upper limit voltage Vpgmmax (the program upper limit voltage Vpgmmax−the potential difference ΔVpgm×2). The prescribed voltage Va may be set equal to the program upper limit voltage Vpgmmax.

On the other hand, if the program voltage Vpgm is judged to be unequal to the prescribed voltage Va, then the control circuit 7 proceeds to the step S06 already described.

At the step S06, the control circuit 7 sets the program voltage Vpgm equal to a voltage raised by the potential difference ΔVpgm. By the way, if the program voltage Vpgm arrives at the program upper limit voltage Vpgmmax, the program voltage Vpgm is fixed to the program upper limit voltage Vpgmmax. The program upper limit voltage Vpgmmax is set considering the capability of the boost circuit already described and the leak current of the NAND flash memory 100.

Preferably, the potential difference ΔVpgm is set equal to the potential difference ΔVpass or less in the same way as the first embodiment. As a result, it is possible to improve the boost efficiency at the floating gate FG of the selected memory cell transistor M.

Then, the control circuit 7 increments the number n of times of looping by one (increments the count by one) (step S07). After the step S07, the control circuit 7 returns to the step S01. Thereafter, a flow similar to the above-described flow is executed.

If the number of times the program operation has been executed is not equal to the upper limit number Loopmax of times of looping in the flow described heretofore, then the program voltage Vpgm is set so as to be raised by the potential difference ΔVpgm, and then the program operation and the verify operation are executed again. Only in the case where the program voltage Vpgm has become equal to the prescribed voltage Va, the intermediate voltage Vpass is raised by the potential difference ΔVpass and fixed.

If, for example, the program voltage Vpgm is equal to the prescribed voltage Va (the program upper limit voltage Vpgmmax−the potential difference ΔVpgm), then the program voltage Vpgm is raised by the potential difference ΔVpgm every program loop as shown in FIG. 13. On the other hand, the intermediate voltage Vpass is raised by the potential difference ΔVpass only when the prescribed number Va is equal to Vpgmmax−ΔVpgm.

If, for example, the program voltage Vpgm is equal to the prescribed voltage Va (the program upper limit voltage Vpgmmax−the potential difference ΔVpgm×2), then the program voltage Vpgm is raised by the potential difference ΔVpgm every program loop as shown in FIG. 14. On the other hand, the intermediate voltage Vpass is raised by the potential difference ΔVpass only when the prescribed number Va is equal to Vpgmmax−ΔVpgm×2.

In this way, the prescribed voltage is set so as to correspond to the state immediately before the program voltage becomes equal to the program upper limit voltage Vpgmmax, such as the program upper limit voltage Vpgmmax−the potential difference ΔVpgm or the program upper limit voltage Vpgmmax−the potential difference ΔVpgm×2. As a result, the intermediate voltage Vpass rises by the potential ΔVpass immediately before the program voltage Vpgm becomes equal to the program upper limit voltage Vpgmmax.

In other words, the boost efficiency is improved and the programming is facilitated for a memory cell transistor M which is difficult to be programmed, immediately before the program voltage Vpgm becomes equal to the program upper limit voltage Vpgmmax.

In the present embodiment, therefore, the probability that a memory cell transistor M which is difficult to be programmed will be completed in programming can be made high as compared with the case where the intermediate voltage Vpass is fixed to a constant value.

Furthermore, in the present embodiment, the intermediate voltage Vpass is kept constant until immediately before the program voltage Vpgm becomes equal to the program upper limit voltage Vpgmmax. As a result, programming is completed early for a memory cell transistor M which can be programmed easily. In this case, therefore, the intermediate voltage Vpass is not raised. As a result, false writing into unselected memory cell transistors M can be suppressed.

In other words, in the present embodiment, false writing into unselected memory cell transistors M can be suppressed as compared with the already described conventional art in which the intermediate voltage Vpass is raised stepwise with the object of improving only the boost efficiency.

In the present embodiment, the case where the intermediate voltage Vpass applied to the control gates CG of all unselected memory cell transistors M is increased by the potential difference ΔVpass has been described.

Alternatively, only the intermediate voltage Vpass applied to the control gate(s) CG of one of or both unselected memory cell transistors M adjacent to the selected memory cell transistor M may be increased by the potential difference ΔVpass, while fixing the intermediate voltage Vpass applied to the control gates CG of remaining unselected memory cell transistors M to an initially set voltage.

In this case, false writing into unselected memory cell transistors M apart from the selected memory cell transistor M can be suppressed.

In the NAND flash memory according to the present embodiment, it is possible to improve the writing efficiency while suppressing false writing as heretofore described.

What is claimed is:

1. A NAND flash memory in which data is written into memory cell transistors, the NAND flash memory comprising:
a first selection gate transistor connected at a first end to a bit line;
a second selection gate transistor connected at a first end to a source line; and
a plurality of memory cell transistors connected in series between a second end of the first selection gate transistor and a second end of the second selection gate transistor, writing data into each of the memory cell transistors by applying a voltage to a control gate of the memory cell transistor,
wherein
program operation is executed to turn on the first selection gate transistor and to turn off the second selection gate transistor, apply an intermediate voltage to control gates of non-selected first memory cell transistors, and apply a program voltage higher than the intermediate voltage to a control gate of a selected second memory cell transistor,
verify operation is executed after the program operation to verify whether a threshold voltage of the selected second memory cell transistor is equal to or higher than a verify level,
if the threshold voltage of the selected second memory cell transistor is lower than the verify level, then a decision is made after the verify operation whether number of times of the program operation is a prescribed upper limit number of times,
if number of times the program operation has been executed is not equal to the prescribed upper limit number of times, then the program voltage is set so as to be raised by a first potential difference and then the program operation and the verify operation are executed again, and
only when the number of times of the program operation has become equal to a prescribed number of times being less than the upper limit number of times, the intermediate voltage is raised by a second potential difference and fixed.

2. The NAND flash memory according to claim 1, wherein the first potential difference is set equal to the second potential difference or less.

3. The NAND flash memory according to claim 1, wherein only the intermediate voltage applied to a control gate of the first memory cell transistor which is adjacent to the second memory cell transistor is raised by the second potential difference.

4. The NAND flash memory according to claim 2, wherein only the intermediate voltage applied to control gates of the first memory cell transistor which is adjacent to the second memory cell transistor is raised by the second potential difference.

5. The NAND flash memory according to claim 1, wherein the prescribed number of times is set equal to the upper limit number of times minus one.

6. The NAND flash memory according to claim 2, wherein the prescribed number of times is set equal to the upper limit number of times minus one.

7. The NAND flash memory according to claim 3, wherein the prescribed number of times is set equal to the upper limit number of times minus one.

8. The NAND flash memory according to claim 1, wherein the prescribed number of times is set equal to the upper limit number of times minus two.

9. The NAND flash memory according to claim 2, wherein the prescribed number of times is set equal to the upper limit number of times minus two.

10. The NAND flash memory according to claim 3, wherein the prescribed number of times is set equal to the upper limit number of times minus two.

11. A NAND flash memory in which data is written into memory cell transistors, the NAND flash memory comprising:
a first selection gate transistor connected at a first end to a bit line;
a second selection gate transistor connected at a first end to a source line; and
a plurality of memory cell transistors connected in series between a second end of the first selection gate transistor and a second end of the second selection gate transistor, writing data into each of the memory cell transistors by applying a voltage to a control gate of the memory cell transistor,
wherein
program operation is executed to turn on the first selection gate transistor and turn off the second selection gate transistor, apply an intermediate voltage to control gates of non-selected first memory cell transistors, and apply a program voltage which is higher than the intermediate voltage to a control gate of a selected second memory cell transistor,
verify operation is executed after the program operation to verify whether a threshold voltage of the selected second memory cell transistor is equal to or higher than a verify level,
if the threshold voltage of the selected second memory cell transistor is lower than the verify level, then a decision is made after the verify operation whether number of times of the program operation is a prescribed upper limit number of times,
if number of times the program operation has been executed is not equal to the prescribed upper limit number of times, then the program voltage is set so as to be raised by a first potential difference and then the program operation and the verify operation are executed again, and
only when the program voltage has become equal to a prescribed voltage, the intermediate voltage is raised by a second potential difference and fixed.

12. The NAND flash memory according to claim 11, wherein the first potential difference is set equal to the second potential difference or less.

13. The NAND flash memory according to claim 11, wherein only the intermediate voltage applied to a control gate of the first memory cell transistor which is adjacent to the second memory cell transistor is raised by the second potential difference.

14. The NAND flash memory according to claim 12, wherein only the intermediate voltage applied to control gates of the first memory cell transistor which is adjacent to the second memory cell transistor is raised by the second potential difference.

15. The NAND flash memory according to claim 11, wherein the prescribed voltage is set equal to the program upper limit voltage.

16. The NAND flash memory according to claim 12, wherein the prescribed voltage is set equal to the program upper limit voltage.

17. The NAND flash memory according to claim 11, wherein the prescribed voltage is set equal to a voltage that is the program upper limit voltage minus the first potential difference.

18. The NAND flash memory according to claim 12, wherein the prescribed voltage is set equal to a voltage that is the program upper limit voltage minus the first potential difference.

19. The NAND flash memory according to claim 11, wherein the prescribed voltage is set equal to a voltage that is the program upper limit voltage minus twice the first potential difference.

20. The NAND flash memory according to claim 12, wherein the prescribed voltage is set equal to a voltage that is the program upper limit voltage minus twice the first potential difference.
